(19) United States
(12) Patent Application Publication
(10) Pub. No.: US 2005/0003088 A1
(43) Pub. Date: Jan. 6, 2005

(54) Method of depositing thin film on wafer

(76) Inventors: Young Hoon Park, Pyungtaek-city (KR); Byung Chul Cho, Pyungtaek-city (KR); Hong Joo Lim, Pyungtaek-city (KR); Sang In Lee, Yongin-city (KR); Sahng Kyoo Lee, Pyungtaek-city (KR); Tae Wook Seo, Pyungtaek-city (KR); Ho Seung Chang, Pyungtaek-city (KR)

Correspondence Address: CANTOR COLBURN, LLP, 55 GRIFFIN ROAD SOUTH, BLOOMFIELD, CT, 06002, US

(21) Appl. No.: 10/882,532

(22) Filed: Jun. 30, 2004

(30) Foreign Application Priority Data
Jul. 1, 2003 (KR) 2003-44398

(51) Int. Cl. C23C 16/00

(52) U.S. Cl. 427/248.1; 427/569; 134/1.1

(57) ABSTRACT

Provided is a method of depositing a thin film on a wafer. The method includes an operation of loading a wafer on a wafer block; an operation of depositing a thin film on the wafer after loading the wafer; an operation of unloading the wafer on which the thin film is deposited from the wafer block; an operation of dry cleaning to remove thin films accumulated on an inner surface of the chamber after unloading the wafer; and an operation of chamber seasoning to form an atmosphere for depositing the main thin film after dry cleaning, wherein the dry cleaning operation comprises: an operation of loading a dummy wafer on the wafer block after unloading the wafer; an operation of main dry cleaning to remove the thin films accumulated on the inner surface of the chamber by dry cleaning by supplying an inert gas and a cleaning gas and supplying a RF energy to the chamber; an operation of sub-dry cleaning to remove an element of the cleaning gas used in the operation of main dry cleaning and remaining on the surface of the chamber by activating a gas selected from the group consisting of H₂, NH₃, Ar, and N₂ by applying RF energy into the chamber while discontinuing supplying of the cleaning gas into the chamber; and an operation of unloading the dummy wafer from the wafer block after the sub-dry cleaning operation.

### BACKGROUND OF THE INVENTION

This application claims the priority of Korean Patent Application No. 2003-44398, filed on Jul. 1, 2003, in the Korean Intellectual Property Office, the disclosure of which is incorporated herein in its entirety by reference.

1. Field of the Invention

The present invention relates to a method of depositing a thin film on a wafer, the method including an operation of dry cleaning an inside of a reactor.

2. Description of the Related Art

To improve yield of semiconductor chips, there have been competitive pursuits in the semiconductor industry to increase wafer size or make superfine line width circuits. Every measure required to deposit a superior thin film on a wafer, to obtain a proper footprint, which refers to an area that a thin-film depositing apparatus occupies, to lower the price of the thin-film depositing apparatus and maintenance costs, to increase the operation rate of equipment and the number of wafers that can be processed in a unit time has been taken. A simple index representing all these factors is the cost of ownership (CoO). The CoO is a very important factor for increasing productivity.

One possibility to lower the CoO is a dry cleaning technique in which thin films accumulated in a reactor is removed without opening the reactor. Accordingly, the efficiency of the dry cleaning is an important indicator for reducing the CoO. So, there has been in the semiconductor industry intensive research into effective cleaning in various aspects.

### SUMMARY OF THE INVENTION

The present invention provides a method of depositing a thin film on a wafer, the method reducing the CoO and including effectively dry cleaning thin films composed of Al₂O₃, HfO₂, HfSiO₄, AlHfO, ZrO₂, or Ta₂O₅, which can not be easily removed by a conventional cleaning method.

The present invention also provides a method of depositing a thin film on a wafer, the method including a dry cleaning process by which vents an element of a cleaning gas can be completely removed from an inner surface of a chamber so that a thin film to be deposited on a run-wafer is not be contaminated by the element of the cleaning gas.

According to an aspect of the present invention, there is provided a method of depositing a thin film on a wafer using an apparatus for depositing the thin film, the apparatus including: a reactor in which a wafer block heats a wafer loaded into a chamber to a predetermined temperature, a top lid that seals the chamber by covering the chamber, a shower head coupled with the top lid and insulated on a lower part, and having first and second spray holes through which a first and a second reaction gases are sprayed to the wafers, respectively; and a RF energy supply unit that supplies RF energy to the reactor, the method comprising: an operation of loading a wafer on the wafer block; an operation of depositing a thin film on the wafer after loading the wafer; an operation of unloading the wafer from the wafer block on which a thin film is deposited; an operation of dry cleaning to remove thin films accumulated on an inner surface of the chamber after unloading the wafer; and an operation of chamber seasoning to form an atmosphere for depositing the main thin film after dry cleaning. The dry cleaning operation comprises: an operation of loading a dummy wafer to load a dummy wafer on the wafer block after unloading the wafer; an operation of main dry cleaning to remove the thin films accumulated on the inner surface of the chamber by dry cleaning by supplying an inert gas and a cleaning gas and supplying RF energy to the chamber; an operation of sub-dry cleaning to remove an element of the cleaning gas used in the operation of main dry cleaning and remaining on the surface of the chamber by activating a gas selected from the group consisting of H₂, NH₃, Ar, and N₂ by applying RF energy into the chamber while discontinuing supplying of the cleaning gas into the chamber; and an operation of unloading a dummy wafer from the wafer block after the sub-dry cleaning operation.

According to another aspect of the present invention, there is provided a method of depositing a thin film using an apparatus for depositing the thin film, the apparatus including: a reactor in which a wafer block heats a wafer loaded to a chamber to a predetermined temperature, a top lid that seals the chamber by covering the chamber, a shower head coupled with the top lid and insulated on a lower part of the top lid, and having first and second spray holes through which first and a second reaction gases are sprayed to the wafers, respectively; and a RF energy supply unit that applies RF energy to the reactor, the method comprising: an operation of loading a wafer on the wafer block; an operation of depositing a thin film on the wafer after loading the wafer; an operation of unloading the wafer from the wafer block on which the thin film is deposited; an operation of reducing a temperature of the wafer block to a predetermined level; an operation of dry cleaning to remove thin films accumulated on an inner surface of the chamber after unloading the wafer; an operation of increasing a temperature and purging the chamber to increase the temperature of the wafer block to a deposition temperature while purging an inert gas into the chamber after the operation of dry cleaning; and an operation of chamber seasoning to form an atmosphere for depositing the main thin film after the operation of dry cleaning. The operation of dry cleaning comprises: an operation of loading a dummy wafer on the wafer block after unloading the wafer; an operation of main dry cleaning to remove the thin films accumulated on the inner surface of the chamber by dry cleaning by supplying an inert gas and a cleaning gas and applying an RF energy to the chamber; an operation of sub-dry cleaning to remove an element of the cleaning gas used in the operation of main dry cleaning and remaining on the surface of the chamber by activating a gas selected from the group consisting of H₂, NH₃, Ar, and N₂ by applying RF energy into the chamber while discontinuing supplying of the cleaning gas into the chamber; and an operation of unloading the dummy wafer from the wafer block after the sub-dry cleaning operation.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view illustrating a structure of an apparatus for depositing a thin film on a wafer, which is used in a method of depositing a thin film according to an embodiment of the present invention;

FIG. 2 is a cross-sectional view illustrating a detailed structure of the apparatus of FIG. 1;

FIG. 3 is a flowchart of a method of depositing a thin film according to a first embodiment of the present invention using the apparatus of FIG. 1;

FIG. 4 is a graph showing an F/V value before and after the dry cleaning of FIG. 3;

FIG. 5 is a graph showing an I/V value before and after the dry cleaning of FIG. 3;

FIG. 6 is a flowchart of a method of depositing a thin film according to a second embodiment of the present invention using the apparatus of FIG. 1 and FIG. 2; and

FIG. 7 is a table summarizing etching rates obtained by a method of depositing a thin film according to the present invention.

### DETAILED DESCRIPTION OF THE INVENTION

The present invention will now be described more fully with reference to the accompanying drawings in which exemplary embodiments of the invention are shown.

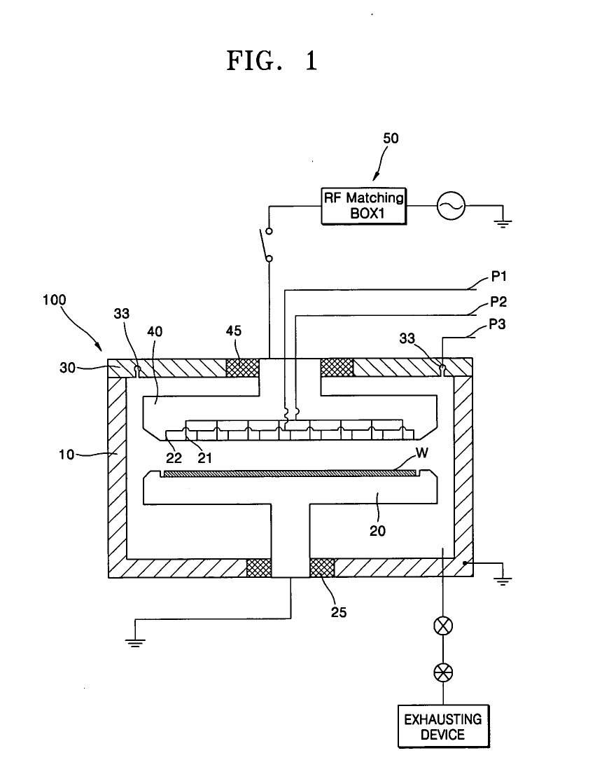

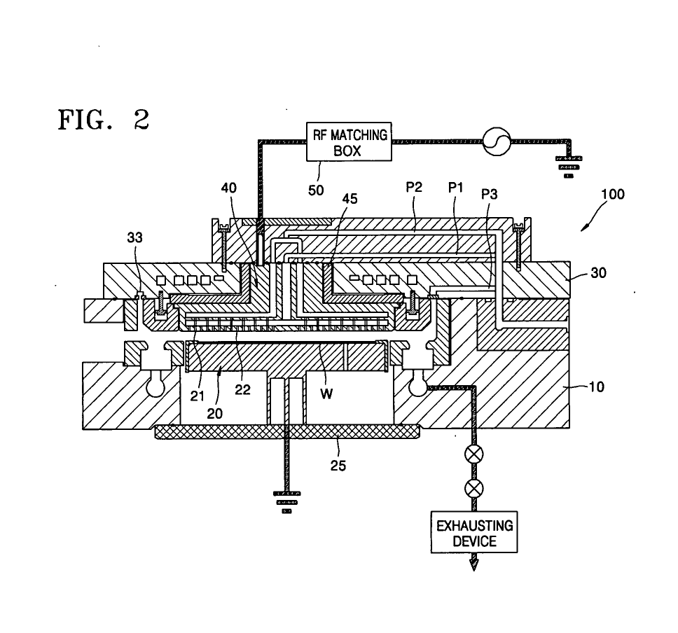

FIG. 1 is a schematic view illustrating a structure of an apparatus for depositing a thin film on a wafer, which is used in a method of depositing a thin film according to an embodiment of the present invention. FIG. 2 is a cross-sectional view illustrating a detailed structure of the apparatus of FIG. 1.

Referring to FIGS. 1 and 2, the apparatus includes a reactor 100 in which a wafer block 20 heats a wafer W loaded into a chamber 10 to a predetermined temperature, a top lid 30 that seals the chamber 10 by covering the chamber 10, and a shower head 40 that sprays a first reaction gas and a second reaction gas on the wafer W and is connected to a lower surface of the top lid 30. At this time, a spray surface parallel to the wafer W and a plurality of first and second spray holes 21 and 22 for spraying the first reaction gas and the second reaction gas, respectively, and not crossing each other are formed on a lower surface of the shower head 40. The shower head 40 is insulated from the top lid 30 by an insulating member 45, and the wafer block 20 also is insulated from the chamber 10 by an insulating member 25. At this time, the wafer block 20 can be a grounded ceramic heater or a metal heater. Also, an RF energy supplying unit 50 for supplying RF energy is connected to the shower head 40 of the reactor 100.

A plurality of gas curtain holes 33 for forming an inert gas curtain on an outer circumference of the wafer block 20, i.e., on an inner wall of the reactor 100, by spraying an inert gas supplied through a third connection line P3 are formed in the top lid 30. A cleaning gas can be sprayed through the gas curtain holes 33 during dry cleaning. In the present invention, the gas curtain holes 33 are formed in the top lid 30 by way of example and are not limited thereto, and can be also formed on a side of the shower head 40.

The first and second spray holes 21 and 22 for spraying the first and second reaction gases entered alternately through the first and second connection lines P1 and P2 over the wafer block 20 are formed in a bottom area of the shower head 40.

A method of depositing a thin film according to a first embedment of the present invention using the apparatus will now be described.

This application is based on Korea Patent Application No. 2003-0015718. That is, this application includes a technique that can remove a possibility of contaminating a device by an element included in the dry cleaning gas, the element adhering to a chamber surface during dry cleaning and penetrating into a wafer even if accumulated thin films are completely removed from a lower surface of the shower head and an upper surface of the wafer block through cleaning. Also, this technique can remove thin films of Al₂O₃, HfO₂, HfSiO₄, AlHfO, ZrO₂, or Ta₂O₅ that are not effectively removed by a conventional cleaning method. The dry cleaning technique will now be described in detail.

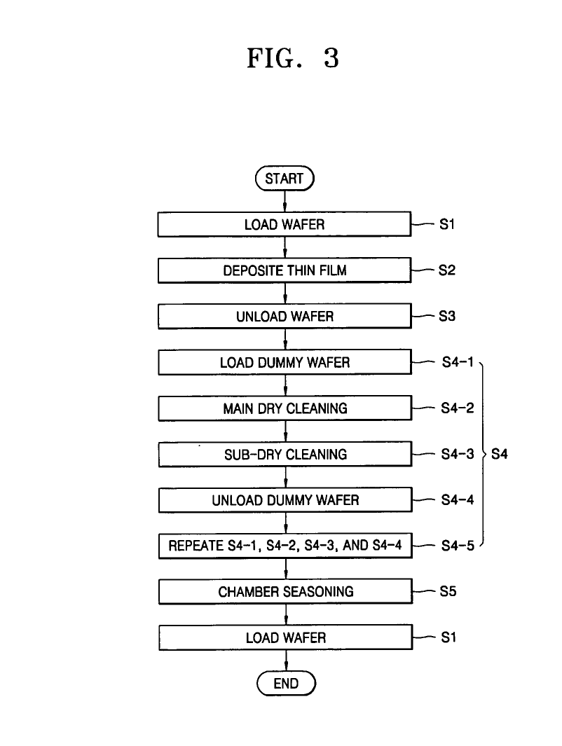

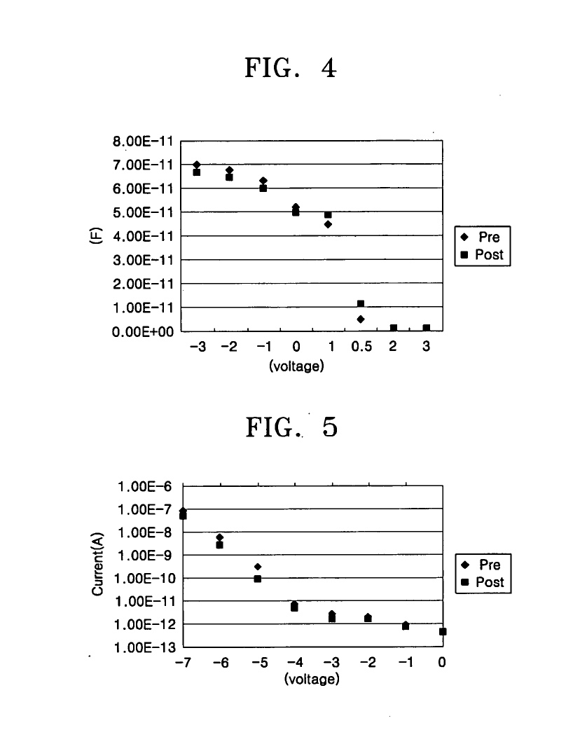

FIG. 3 is a flowchart for explaining a method of depositing a thin film according to a first embodiment of the present invention using the apparatus of FIG. 1. FIG. 4 is a graph showing a F/V value before and after the dry cleaning of FIG. 3, and FIG. 5 is a graph showing an I/V value before and after the dry cleaning of FIG. 3.

Referring to FIG. 3, the method of depositing a thin film according to a first embodiment of the present invention includes an operation S1 of loading a wafer W on a wafer block 20, an operation S2 of depositing an ADL thin film on the wafer W after loading the wafer W, an operation S3 of unloading the wafer W on which the ADL thin film is deposited from the wafer block 20, an operation S4 of dry cleaning to remove accumulated thin films in the chamber 10 after unloading the wafer W, and an operation S5 of chamber seasoning to form an atmosphere for depositing a thin film after the operation S4 of dry cleaning.

At this time, the operation S4 of dry cleaning comprises an operation S4-1 of loading a dummy wafer on the wafer block 20 after unloading the wafer W, an operation S4-2 of main dry cleaning to remove thin films accumulated on an inner surface of the chamber 10 by dry cleaning, an operation S4-3 of sub-dry cleaning to remove an element of the cleaning gas existed on an inner surface of the chamber 10, an operation S4-4 of unloading the dummy wafer from the wafer block 20 to transport it outside of the reactor 100, and an operation S4-5 of sequentially repeating the operations S4-1, S4-2, S4-3, and S4-4 at least twice using new dummy wafers.

The operation S1 of loading the wafer, the operation S2 of depositing the thin film, and the operation S3 of unloading the wafer are operations for depositing a thin film. Particularly, in the operation S2 of depositing a thin film, the ALD thin film is deposited on the wafer W by alternately spraying the first reaction gas and the second reaction gas through the first and second spray holes 21 and 22. The final wafer W on which a thin film is formed is unloaded from the wafer block 20 right before the dry cleaning and transported outside of the reactor 100.

Meanwhile, a gas curtain may be formed on an inner wall of the reactor 100 spraying an inert gas through the gas curtain holes 33 formed in the top lid or on a side of the shower head 40 while depositing the thin film. The gas curtain can minimize the deposition of the thin film with the inner wall of the reactor 100 by reducing the contact of the first and second reaction gases to the inner wall of the reactor 100.

Through the operations described above, a single oxide film or a multiple oxide film such as an Al₂O₃ film, a HfO₂ film, a HfSiO₄ film, an AlHfO film, an ZrO₂ film, or a Ta₂O₅ film is formed on the wafer W.

After the series of operations, the operation S4 of dry cleaning for cleaning an inside of the chamber 10 is performed. The operation S4-1 of loading a dummy wafer is a preliminary operation for main dry cleaning, and in this operation, the dummy wafer is loaded to the wafer block 20.

When plasma is formed in the reactor 100, the dry cleaning is achieved through collision of the cleaning gas activated by the plasma in the chamber 10. However, in this process, a surface of the wafer block 20 may be damaged by the cleaning gas, and in a worst case, thin film particles separated from the shower head 40 may be re-deposited on a surface of the wafer block 20.

The operation S4-1 of loading a dummy wafer is an operation for reducing the damage of the wafer block 20 and for preventing the re-deposition of the cleaned thin film on the surface of the wafer block 20 during the dry cleaning.

The operation S4-2 of main dry cleaning is an operation for removing accumulated thin films on an inner surface of the chamber 10 using a cleaning gas activated by plasma which is formed by supplying an inert gas and a cleaning gas into the chamber and supplying RF energy to the shower head 40. The activated cleaning gas particles separate the thin films accumulated on the shower head 40 or the wafer block 20 by colliding with the inner surface of the chamber 10. At this time, an RF energy source of 13.56 MHz is used and an RF power is preferably 0.2-5 KW. In the present invention, an RF energy of 1.5 KW is used for cleaning the Al₂O₃ film.

When one of thin films such as an Al₂O₃ film, a HfO₂ film, a HfSiO₄ film, an AlHfO film, an ZrO₂ film, or a Ta₂O₅ film are accumulated in the chamber 10, the thin films are not easily removed by a conventional thermal dry cleaning method. In the present invention, BCl₃ gas or a diluted BCl₃ gas with a dilution gas is used as the cleaning gas to clean the thin films. The dilution gas can be an inert gas such as Ar or He, or pure nitrogen or mixed nitrogen.

The operation S4-3 of sub-dry cleaning is an operation for generating plasma by supplying a gas selected from the group consisting of H₂, NH₃, Ar, and N₂ into the chamber 10 and supplying RF energy to the shower head 40 in a state of blocking the cleaning gas used from entering the chamber 10 during the main dry cleaning operation. The generated plasma activates the selected gas, and the activated gas cleans the element of the cleaning gas existed on an inner surface (the shower head and the wafer block) of the chamber 10.

Features of operational conditions in the operation S4-3 of sub-dry cleaning are the blocking entering the cleaning gas used in the operation S4-2 of main dry cleaning and selections of an inert gas and flowrate supplying into the chamber 10. That is, the gas entering into the chamber 10 may be a gas mixture without Ar, or, if Ar is included, may be a gas mixture of X+Ar. Here, if X is a single gas or a gas mixture containing H or N, a flowrate ratio of X/Ar is set so that the value of X/Ar is greater than 1. The RF energy supplied to the shower head 40 during the sub-cleaning operation is between 0.1 KW and 4 KW.

During the operation S4-3 of sub-dry cleaning, Ar is not independently used for the cleaning gas because, there may be some differences according to the conditions of using, temperature of the wafer block 20 increases about 100° C. per minute. That is, if the sub-cleaning is performed using only Ar when the temperature of the wafer block 20 is 300° C., the temperature of the wafer block 20 is increased to almost 600° C. by supplying approximately 1.5 KW of RF energy for 3 minutes resulting in increasing temperature of the inner walls of the chamber 10 and the top lid 30. Therefore, it is preferable not to perform the sub-dry cleaning using only Ar to avoid rapid temperature increase in the chamber 10.

The operation S4-4 is an operation for unloading and transporting the wafer outside the wafer block 20 loaded during operations S4-2 and S4-3 to protect the wafer block 20.

The operations S4-5 is an operation for sequentially performing the operations S4-1, S4-2, S4-3, and S4-4 at least twice until sufficient cleaning is achieved. During the operation S4-5, a purge must be sufficiently performed and each operation has to be performed using a new dummy wafer.

The operation S5 of chamber seasoning is performed after performing the operation S4 of dry cleaning. The operation S5 of chamber seasoning is a preliminary operation for depositing a thin film and comprises purging an inert gas into the chamber 10, pre-coating particles remained in the chamber as by-products from the cleaning on an inner surface of the chamber 10, and sub-depositing a thin film using a dummy wafer.

The chamber purging is an operation for removing particles remained in the chamber 10 to the outside after dry cleaning.

Pre-coating is an operation for fixing particles that could remain on a surface of the shower head 40 and the wafer block 20 after purging, and is performed by spraying the first and second reaction gases into the chamber 10 through the shower head 40 without a dummy wafer. The pre-coating is performed in a greater rate than depositing a thin film on a wafer W. For this purpose, purge times of the first and second gases are reduced or the first and second gases are sprayed simultaneously into the reactor 100 as in the CVD method.

Sub-depositing a thin film is performed by spraying the first and second gases into the chamber 10 after loading the dummy wafer on the wafer block 20 after pre-coating. Through the sub-depositing a thin film, especially depositing a thin film on the shower head 40, a deposition rate for depositing a thin film on the wafer W can be increased.

After the operation S5 of chamber seasoning, an Al₂O₃ film is deposited on a pattern wafer to measure the electrical characteristics, and at this time, the Al₂O₃ film is deposited over 68 cycles.

The variation of capacitance F according to the variation of voltage V of a capacitor of a pattern wafer on which the Al₂O₃ film is deposited, that is, an F-V curve is shown in FIG. 4, and the variation of a leakage current according to the voltage variation, that is, an I-V curve is shown in FIG. 5. The symbol ‘♦pre’ indicates electrical characteristics of the pattern wafer before dry cleaning, and the symbol ‘▪post’ indicates electrical characteristics of the pattern wafer after dry cleaning.

After performing 15,000 cycles for depositing an Al₂O₃ thin film, the main dry cleaning and sub-dry cleaning were performed for four minutes and forty seconds. Referring to FIGS. 4 and 5, no symptoms of reducing electrical characteristics after dry cleaning comparing to the electrical characteristics before dry cleaning are revealed. That is, according to the present invention, the complete removal of accumulated thin films on an inner surface of the chamber 10 and non-occurrence of a phenomenon such as the reduction of electrical characteristics of the wafer by an element included in the cleaning gas are confirmed. For example, the pattern wafer is not contaminated by an element such as B or Cl even if the dry cleaning is performed using BCl₃.

A method of depositing a thin film according to a second embodiment using the apparatus for depositing a thin film will now be described.

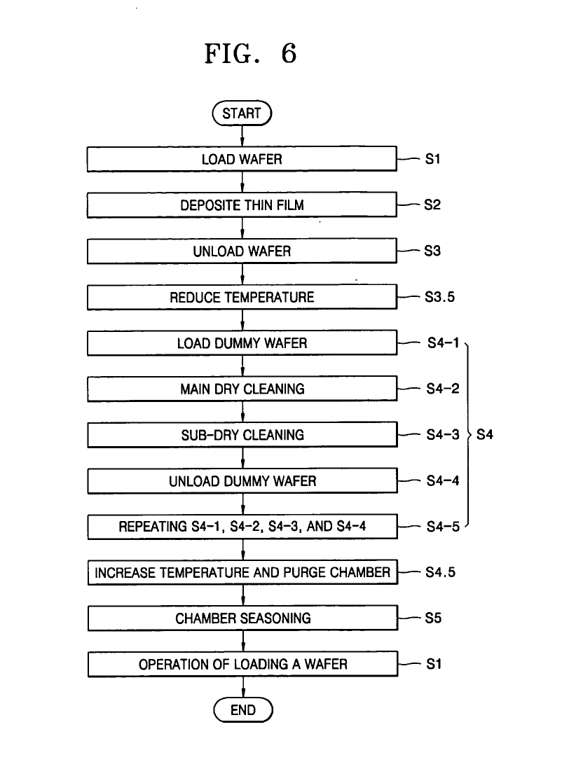

FIG. 6 is a flow chart for explaining a method of depositing a thin film according to a second embodiment of the present invention using the apparatus for depositing a thin film of FIG. 1 and FIG. 2.

Referring to FIG. 6, the method of depositing a thin film according to the second embodiment comprises an operation S1 of loading a wafer W on the wafer block 20, an operation S2 of depositing a thin film such as an ALD thin film on the wafer W, an operation S3 of unloading the wafer W on which the thin film is deposited from the wafer block 20 and to transport the wafer W to the outside, an operation S3.5 of reducing a temperature of the wafer block 20 to a predetermined level which is lower than the deposition temperature after unloading the wafer W, an operation S4 of dry cleaning to remove accumulated thin films in the chamber 10 after reducing the temperature of the wafer block 20, an operation S4.5 of increasing a temperature and purging the chamber 10 to increase the temperature of the wafer block 20 to a deposition temperature while purging an inert gas into the chamber 10 after dry cleaning, and an operation S5 of chamber seasoning to form an atmosphere for main depositing a thin film.

Differences of the second embodiment from the first embodiment are in that the operation S3.5 of reducing the temperature is performed after performing the operation S3 of unloading the wafer, the operation S4 of dry cleaning is performed after performing the operation S3.5 of reducing the temperature, the operation S4.5 of increasing temperature and purging the chamber 10 are performed after performing the operation S4 of dry cleaning, and the operation S5 of chamber seasoning is performed after performing the operation S4.5 of increasing the temperature and purging the chamber 10.

Here, the ALD thin film is deposited on the wafer W through the operation S1 of loading the wafer, the operation S2 of depositing the thin film, and the operation S3 of unloading the wafer. The inside of the chamber 10 is cleaned through the operation S4 of dry cleaning and the operation for depositing the main thin film is prepared through the operation S5 of chamber seasoning. At this time, the thin film to be deposited on the wafer W is one of an Al₂O₃ film, an HfO₂ film, an HfSiO₄ film, an AlHfO film, a ZrO₂ film, and a Ta₂O₅ film. The descriptions of the above operations are omitted since they are practically the same as in the first embodiment.

The operation S4 of dry cleaning comprises an operation S4-1 of loading a dummy wafer on the wafer block 20 after the operation S3.5 of reducing the temperature, an operation S4-2 of main dry cleaning to remove the thin films accumulated on an inner surface of the chamber 10 by dry cleaning, an operation S4-3 of sub-dry cleaning to remove an element of the cleaning gas existing on an inner surface of the chamber 10 after the operation S4-2 of main dry cleaning, an operation S4-4 of unloading the dummy wafer from the wafer block 20 to transport it to the outside after the operation S4-3 of sub-dry cleaning, and an operation S4-5 of sequentially repeating the operations from the operations S4-1, S4-2, S4-3, and S4-4 at least twice using a new dummy wafer each time.

In the operation S4-2 of main dry cleaning, BCl₃ gas or a diluted BCl₃ gas with a dilution gas is used as the cleaning gas to clean the thin films. The dilution gas can be an inert gas such as Ar or He, or pure nitrogen or mixed nitrogen. RF energy is supplied to the chamber 10. The RF energy supplied to the shower head 40 is 0.2-5 KW.

In the operation S4-3 of sub-dry cleaning, the gas entering into the chamber 10 may be a gas mixture without Ar, or, if Ar is included, may be a gas mixture of X+Ar. Here, if X is a single gas or a gas mixture containing H or N, a flowrate ratio of X/Ar is set so that the value of X/Ar is greater than 1. RF energy supplied to the shower head 40 during the operation S4-3 of sub-dry cleaning is 0.1-4 KW.

The operation S5 of chamber seasoning comprises an operation of purging an inert gas into the chamber 10, an operation of pre-coating to fix particles on the inner surface of the chamber 10, in which the particles are generated as by products remained in an inner surface of the chamber 10, and an operation of depositing a sub-thin film to deposit a thin film using the dummy wafer. The basic concept of the second embodiment is identical to the concept of the first embodiment but the operations of reducing and increasing the temperature are added to the first embodiment.

By a conventional wet cleaning method, not by a dry cleaning method, about 9,000-10,000 pieces of wafers can be deposited per cycle of wet cleaning based on depositing an Al₂O₃ thin film with a thickness of 48 Å using the apparatus for depositing a thin film of FIGS. 1 and 2, and recently, the cycle of wet cleaning is increased with the development of techniques.

Accordingly, in order to be advantageous over the wet cleaning method, the dry cleaning method has to have a greater cleaning rate and a greater cleaning cycle than those of the wet cleaning method. Or, there is no merit with respect to the CoO. For this purpose, a condition for dry cleaning to have a room for increasing the temperature of the wafer block 20 and the shower head 40 is required. Therefore, the second embodiment further comprises the operation S3.5 of reducing the temperature of the wafer block 20 and the operation S4.5 of increasing the temperature and purging the chamber 10.

That is, after reducing the temperature of the wafer block 20, a series of plasma cleanings are performed by loading new dummy wafers as in the first embodiment, and the plasma dry cleaning is repeated until a desired cleaning level is obtained. When cleaning is completed, the operation S4.5 of increasing the temperature and purging the chamber 10 is preformed. The purpose of purging the chamber 10 while increasing the temperature of the chamber 10 is to purge out the fine particles generated during dry cleaning and adhered on an inner surface of the chamber 10. When the temperature increasing is completed, the operation S5 of chamber seasoning is performed as in the first embodiment, and then a new wafer-run can be commenced.

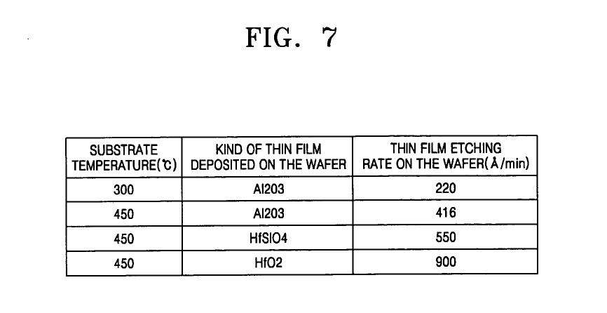

FIG. 7 is a table summarizing etching rates obtained by a method of depositing a thin film according to the present invention. At this time, a pressure of the chamber was maintained at 183 Torr, flowrates of BCl₃ and Ar were maintained at 70 and 30 sccm, respectively, and applied RF power for plasma generation was 1.5 KW.

At an equal wafer temperature (450° C.), the etching rate of an Al₂O₃ film on a wafer is 416 Å/min. However, in the case of a HfO₂ film and HfSiO₄ film, the etching rates are 900 and 550 Å/min, respectively. Accordingly, it can be said that the etching rates of the HfO₂ film and HfSiO₄ film at the shower head 40 are greater than the etching rate of the Al₂O₃ film. According to the data disclosed in the industry, the order of etching efficiency of plasma dry etching is HfO₂, Al₂O₃, ZrO₂, and the test result of the present invention matches this order.

As depicted in FIGS. 1 and 2, the first and second embodiments of the present invention are not limited to the cleaning of the Al₂O₃ film, but applied to all thin films such as a HfO₂ film, a HfSiO₄ film, a ZrO₂ film, an AlHfO film, and a Ta₂O₅ film that are not cleaned by a thermal dry cleaning without plasma.

The method of depositing a thin film according to the present invention can prevent reducing of yield and electrical characteristics of a thin film of a run-wafer deposited after dry cleaning by minimizing contamination by elements of the cleaning gas.

Furthermore, according to the present invention, CoO can be reduced and the films such as a HfO₂ film, a HfSiO₄ film, a ZrO₂ film, an AlHfO film and a Ta₂O₅ film that are not being cleaned by a conventional cleaning method can be cleaned without opening a reactor.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of depositing a thin film on a wafer using an apparatus for depositing the thin film, the apparatus including: a reactor in which a wafer block heats a wafer loaded into a chamber to a predetermined temperature, a top lid that seals the chamber by covering the chamber, a shower head coupled with the top lid and insulated on a lower part, and having first and second spray holes through which a first and a second reaction gases are sprayed to the wafers, respectively; and a RF energy supply unit that supplies RF energy to the reactor,
the method comprising:
an operation of loading a wafer on the wafer block;
an operation of depositing a thin film on the wafer after loading the wafer;
an operation of unloading the wafer from the wafer block on which a thin film is deposited;
an operation of dry cleaning to remove thin films accumulated on an inner surface of the chamber after unloading the wafer; and
an operation of chamber seasoning to form an atmosphere for depositing the main thin film after dry cleaning,
wherein the dry cleaning operation comprises:
an operation of loading a dummy wafer to load a dummy wafer on the wafer block after unloading the wafer;
an operation of main dry cleaning to remove the thin films accumulated on the inner surface of the chamber by dry cleaning by supplying an inert gas and a cleaning gas and supplying RF energy to the chamber;
an operation of sub-dry cleaning to remove an element of the cleaning gas used in the operation of main dry cleaning and remaining on the surface of the chamber by activating a gas selected from the group consisting of H₂, NH₃, Ar, and N₂ by applying RF energy into the chamber while discontinuing supplying of the cleaning gas into the chamber; and
an operation of unloading a dummy wafer from the wafer block after the sub-dry cleaning operation.

2. The method of claim 1, further comprising an operation of sequentially repeating the operations from the operation of loading the dummy wafer to the operation of unloading the dummy wafer at least twice using new dummy wafers.

3. The method of claim 1, wherein the thin film deposited on the wafer is one of an HfO₂ film, a HfSiO₄ film, a ZrO₂ film, an AlHfO film and a Ta₂O₅ film.

4. The method of claim 1, wherein, in the operation of main dry cleaning, the cleaning gas is one of a BCl₃ gas and a BCl₃ gas diluted with a dilution gas selected from the group consisting of an inert gas, including Ar and He, a pure nitrogen gas, and a nitrogen-containing mixed gas.

5. The method of claim 4, wherein the RF power supplied to the shower head is 0.2-5 KW.

6. The method of claim 1, wherein the gas used in the operation of sub-dry is a gas mixture not containing Ar or a gas mixture containing Ar and expressed as X+Ar where X is a pure gas or a gas mixture containing H or N and a flowrate ratio of X/Ar is set to be greater than 1.

7. The method of claim 6, wherein, in the operation of sub-dry cleaning, an RF energy supplied to the shower head is 0.1-4 KW.

8. The method of claim 1, wherein the operation of chamber seasoning comprises:
an operation of purging the chamber to purge an inert gas in the chamber;
an operation of pre-coating to fix particles, as by-products of the cleaning, remained on an inner surface of the chamber on the inner surface of the chamber; and
an operation of depositing a sub-thin film to deposit a thin film using a dummy wafer.

9. A method of depositing a thin film using an apparatus for depositing the thin film, the apparatus including: a reactor in which a wafer block heats a wafer loaded to a chamber to a predetermined temperature, a top lid that seals the chamber by covering the chamber, a shower head coupled with the top lid and insulated on a lower part of the top lid, and having first and second spray holes through which first and a second reaction gases are sprayed to the wafers, respectively; and a RF energy supply unit that applies RF energy to the reactor, the method comprising:
an operation of loading a wafer on the wafer block;
an operation of depositing a thin film on the wafer after loading the wafer;
an operation of unloading the wafer from the wafer block on which the thin film is deposited;
an operation of reducing a temperature of the wafer block to a predetermined level;
an operation of dry cleaning to remove thin films accumulated on an inner surface of the chamber after unloading the wafer;
an operation of increasing a temperature and purging the chamber to increase the temperature of the wafer block to a deposition temperature while purging an inert gas into the chamber after the operation of dry cleaning; and
an operation of chamber seasoning to form an atmosphere for depositing the main thin film after the operation of dry cleaning,
wherein the operation of dry cleaning comprises:
an operation of loading a dummy wafer on the wafer block after unloading the wafer;
an operation of main dry cleaning to remove the thin films accumulated on the inner surface of the chamber by dry cleaning by supplying an inert gas and a cleaning gas and applying an RF energy to the chamber;
an operation of sub-dry cleaning to remove an element of the cleaning gas used in the operation of main dry cleaning and remaining on the surface of the chamber by activating a gas selected from the group consisting of H₂, NH₃, Ar, and N₂ by applying RF energy into the chamber while discontinuing supplying of the cleaning gas into the chamber; and
an operation of unloading the dummy wafer from the wafer block after the sub-dry cleaning operation.

10. The method of claim 9, further comprising an operation of sequentially repeating the operations from the operation of loading the dummy wafer to the operation of unloading the dummy wafer at least twice using a new dummy wafer each time.

11. The method of depositing a thin film of claim 9, wherein the thin film deposited on the wafer is one of an HfO₂ film, a HfSiO₄ film, a ZrO₂ film, an AlHfO film and a Ta₂O₅ film.

12. The method of depositing a thin film of claim 1, wherein, in the operation of main dry cleaning, the cleaning gas is one of a BCl₃ gas and a BCl₃ gas diluted with a dilution gas selected from the group consisting of an inert gas, including Ar and He, a pure nitrogen gas, and a nitrogen-containing mixed gas.

13. The method of depositing a thin film of claim 12, wherein the RF power supplied to the shower head is 0.2-5 KW.

14. The method of depositing a thin film of claim 9, wherein the gas used in the operation of sub-dry cleaning is a gas mixture not containing Ar or a gas mixture containing Ar and expressed as X+Ar where X is a pure gas or a gas mixture containing H or N, and a flowrate ratio of X/Ar is set to be greater than 1.

15. The method of depositing a thin film of claim 14, wherein, in the operation of sub-dry cleaning, the RF energy supplied to the shower head is 0.1-4 KW.

16. The method of claim 9, wherein the operation of chamber seasoning comprises:
an operation of purging the chamber to purge an inert gas in the chamber;
an operation of pre-coating to fix particles, as by-products of the cleaning, remained on an inner surface of the chamber on the inner surface of the chamber; and
an operation of depositing a sub-thin film to deposit a thin film using a dummy wafer.
